(19) United States
(12) Patent Application Publication
(10) Pub. No.: US 2021/0035916 A1
(43) Pub. Date: Feb. 4, 2021

(54) SEMICONDUCTOR PACKAGE

(71) Applicant: NANYA TECHNOLOGY CORPORATION, New Taipei city (TW)

(72) Inventor: Chang-Chun HSIEH, Changhua County (TW)

(21) Appl. No.: 16/524,175

(22) Filed: Jul. 29, 2019

(51) Int. Cl. H01L 23/552; H01L 23/00; H01L 23/498; H01L 23/31

(52) U.S. Cl. CPC H01L 23/552; H01L 24/48; H01L 24/33; H01L 24/73; H01L 23/49816; H01L 2924/1436; H01L 23/3128; H01L 2224/73265; H01L 2224/73215; H01L 2224/33181; H01L 23/49827

(57) ABSTRACT

A semiconductor package includes a substrate, a semiconductor die, a dummy die, a conductive layer, at least one first conductive wire, and at least one second conductive wire. The semiconductor die is disposed on the substrate. The dummy die is disposed on the semiconductor die. The conductive layer is disposed on the dummy die. The first conductive wire electrically connects the semiconductor die to a signal source. The second conductive wire electrically connects the conductive layer to a ground reference.

### BACKGROUND

### Field of Invention

The present disclosure relates to a semiconductor package.

### Description of Related Art

When a dynamic random access memory (DRAM) is in operation, electromagnetic waves, which cause interference with other surrounding electronic products, are generated due to electromagnetic effects, and thus resulting in product failure. This phenomenon is referred to as an electromagnetic interference (EMI). On the other hand, electromagnetic waves emitted by other surrounding electronic products also interfere with the DRAM.

As such, it is desirable to develop a DRAM device with an improved anti-interference ability, also referred to as an electromagnetic sensibility (EMS), to prevent electromagnetic interference.

### SUMMARY

The present disclosure relates in general to a semiconductor package.

According to an embodiment of the present disclosure, a semiconductor package includes a substrate, a semiconductor, a dummy die, a conductive layer, at least one first conductive wire, and at least one second conductive wire. The semiconductor die is disposed on the substrate. The dummy die is disposed on the semiconductor die. The conductive layer is disposed on the dummy die. The first conductive wire electrically connects the semiconductor die to a signal source. The second conductive wire electrically connects the conductive layer to a ground reference.

In an embodiment of the present disclosure, a vertical projection area of the conductive layer on the substrate covers a vertical projection area of the semiconductor die on the substrate.

In an embodiment of the present disclosure, the semiconductor package further includes a first molding compound material encapsulating the semiconductor die and the dummy die.

In an embodiment of the present disclosure, the first molding compound material further encapsulates the first conductive wire and the second conductive wire.

In an embodiment of the present disclosure, the semiconductor package further includes a first adhesive layer and a second adhesive layer. The first adhesive layer attaches the semiconductor die to the substrate. The second adhesive layer attaches the dummy die to the semiconductor die.

In an embodiment of the present disclosure, the substrate further includes a dielectric layer and a plurality of conductive pads. The dielectric layer has a first surface and a second surface. The conductive pads are disposed on the first surface and the second surface of the dielectric layer.

In an embodiment of the present disclosure, the substrate further includes a plurality of traces interconnecting the conductive pads on the first surface of the dielectric layer or the conductive pads on the second surface of the dielectric layer.

In an embodiment of the present disclosure, the substrate further includes a plurality of conductive structures extending through the dielectric layer. The conductive structures electrically connect the conductive pads on the first surface of the dielectric layer to the corresponding conductive pads on the second surface of the dielectric layer.

In an embodiment of the present disclosure, the semiconductor package further includes a plurality of soldering balls electrically connected to the conductive pads on the second surface.

In an embodiment of the present disclosure, the substrate further includes two soldering masks disposed on the first surface and the second surface of the dielectric layer, respectively.

In an embodiment of the present disclosure, the semiconductor package further includes a second molding compound material having a first portion and a second portion. The first portion penetrates through the substrate, and second portion is disposed on a bottom surface of the substrate.

In an embodiment of the present disclosure, the first portion of the second molding compound material is in contact with a bottom surface of the semiconductor die.

In an embodiment of the present disclosure, the second molding compound material encapsulates the first conductive wire.

In an embodiment of the present disclosure, a width of the first portion of the second molding compound material is smaller than a width of the second portion of the second molding compound material.

In an embodiment of the present disclosure, the semiconductor package further includes a first adhesive layer and a second adhesive layer. The first adhesive layer attaches the semiconductor die to the substrate. The second adhesive layer attaches the dummy die to the semiconductor die.

In an embodiment of the present disclosure, the first adhesive layer surrounds a portion of the first portion of the second molding compound material.

In an embodiment of the present disclosure, the first adhesive layer is in contact with the portion of the first portion of the second molding compound material.

In an embodiment of the present disclosure, the semiconductor package further includes a dielectric layer and a plurality of conductive pads. The dielectric layer has a first surface and a second surface. The conductive pads are disposed on the first surface and the second surface of the dielectric layer.

In an embodiment of the present disclosure, the semiconductor package further includes a plurality of soldering balls electrically connected to portions of the conductive pads on the second surface of the dielectric layer.

In an embodiment of the present disclosure, the second portion of the second molding compound material covers portions of the conductive pads on the second surface of the dielectric layer.

In the aforementioned embodiments of the present disclosure, since the dummy die is disposed on the semiconductor die, and the conductive layer is disposed on the dummy die to be electrically connected to the ground reference by the second conductive wire, electromagnetic waves generated by the semiconductor die are blocked from interfering with other surrounding electronic devices, and thus the electromagnetic interference (EMI) between the semiconductor package and other surrounding electronic products is prevented. Additionally, the electromagnetic sensibility (EMS) of the semiconductor package is further improved.

### BRIEF DESCRIPTION OF THE DRAWINGS

The disclosure can be more fully understood by reading the following detailed description of the embodiments, with reference made to the accompanying drawings as follows:

FIG. 1 is a cross-sectional view of a process at various stages of a manufacturing method of a semiconductor package according to an embodiment of the present disclosure;

FIG. 2 is a top view of a process at various stages of a manufacturing method of a semiconductor package according to an embodiment of the present disclosure;

FIGS. 3-5 are cross-sectional views of a process at various stages of a manufacturing method of a semiconductor package according to an embodiment of the present disclosure;

FIG. 6 is a top view of the semiconductor package shown in FIG. 5, in which a first molding compound material is omitted;

FIG. 7 is a cross-sectional view of a process at various stages of a manufacturing method of a semiconductor package according to another embodiment of the present disclosure;

FIG. 8 is a top view of a process at various stages of a manufacturing method of a semiconductor package according to another embodiment of the present disclosure;

FIGS. 9-11 are cross-sectional views of a process at various stages of a manufacturing method of a semiconductor package according to another embodiment of the present disclosure;

FIG. 12 is a top view of the semiconductor package shown in FIG. 11, in which a first molding compound material is omitted; and

FIG. 13 is a bottom view of the semiconductor package shown in FIG. 11, in which soldering balls are omitted.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In the embodiments of the present disclosure, a semiconductor package and a method of manufacturing the same are provided. For the purpose of simplicity and clarity, the method of manufacturing the semiconductor package will be described first in the article. Furthermore, some of the secondary elements may be omitted in the drawings accompanying the following embodiments.

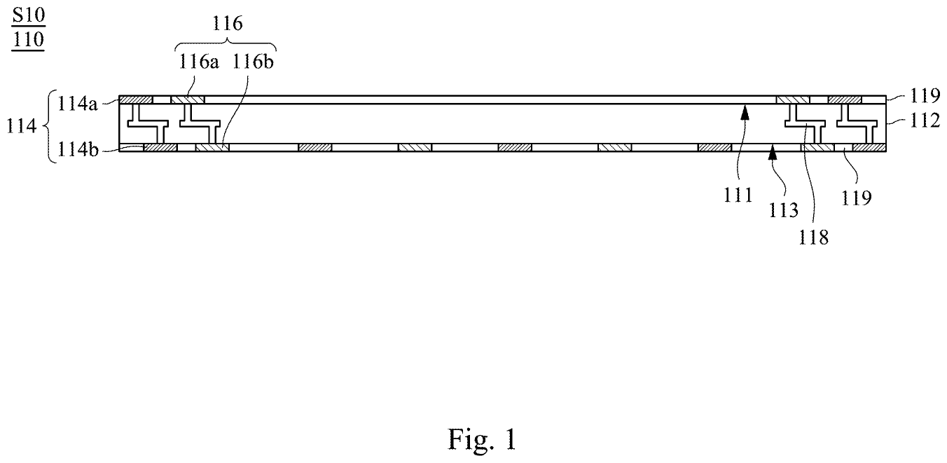

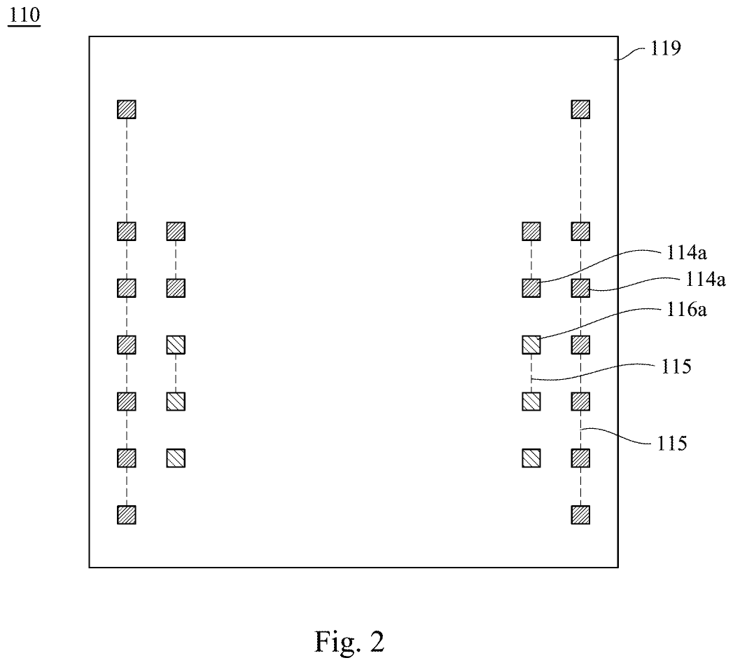

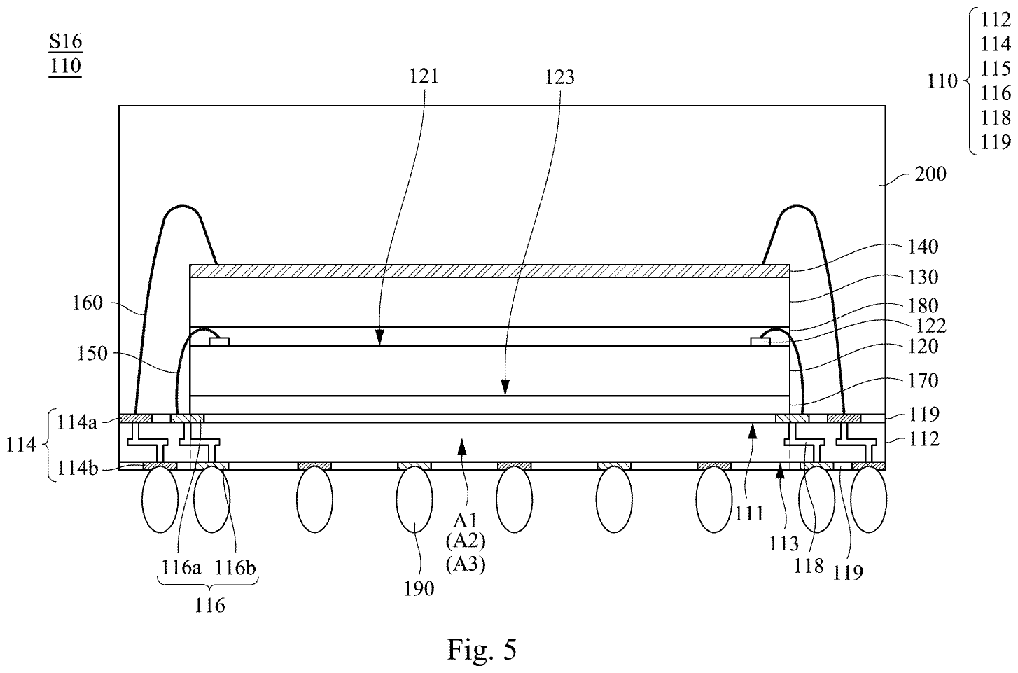

Reference is made to FIGS. 1 and 2, which are a cross-sectional view and a top view of step S10 of forming a semiconductor package 100 of FIG. 5. In step S10, a dielectric layer 112 having a first surface 111 and a second surface 113 is provided. A plurality of first conductive pads 114, a plurality of traces 115, and a plurality of second conductive pads 116 are disposed on the dielectric layer 112. A plurality of conductive structures 118 are formed to penetrate through the dielectric layer 112. Various electrical interconnections are formed between the first conductive pads 114 and between the second conductive pads 116 by the traces 115 and the conductive structures 118. Two soldering masks 119 are respectively disposed on the first surface 111 and the second surface 113 of the dielectric layer 112. After that, a substrate 110 including the dielectric layer 112, the first conductive pads 114, the traces 115, the second conductive pads 116, the conductive structures 118, and the soldering masks 119 can be formed.

In some embodiments, the first conductive pads 114 are electrically connected to a ground reference while the second conductive pads 116 are electrically connected to a signal source or a power source. In detail, some of the second conductive pads 116 are electrically connected to the signal source, and the other of the second conductive pads 116 are electrically connected to the power source. For the purpose of simplicity and clarity, in the following description, the first conductive pads 114 on the first surface 111 and the second surface 113 of the dielectric layer 112 are respectively referred to as the first conductive pads 114a and the first conductive pads 114b, and the second conductive pads 116 on the first surface 111 and the second surface 113 of the dielectric layer 112 are respectively referred to as the second conductive pads 116a and the second conductive pads 116b.

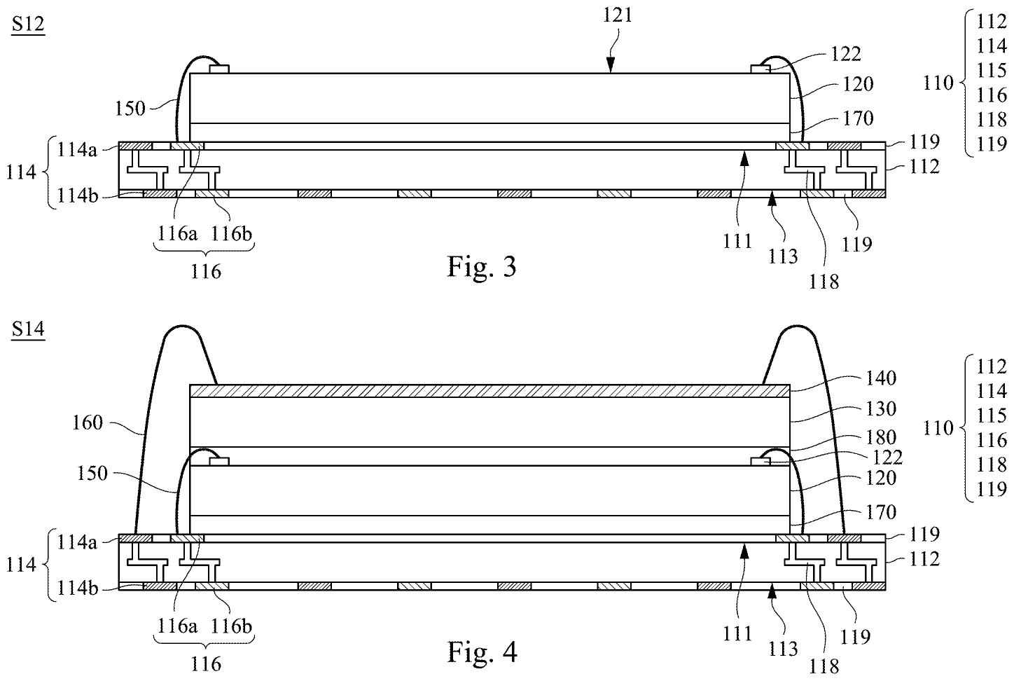

Reference is made to FIG. 3, which is a cross-sectional view of step S12 of forming the semiconductor package 100 of FIG. 5. In step S12, a first adhesive layer 170 is formed on one of the soldering masks 119 disposed on the first surface 111 of the dielectric layer 112. A semiconductor die 120 is then attached to the substrate 110 by the first adhesive layer 170. A plurality of third conductive pads 122 are disposed on a top surface 121 of the semiconductor die 120. After that, a plurality of first conductive wires 150 are respectively connected from the third conductive pads 122 to the conductive pads on the first surface 111 of the dielectric layer 112. In detail, some of the first conductive wires 150 are connected from the third conductive pads 122 to the first conductive pads 114a, and the other of the first conductive wires 150 are connected from the third conductive pads 122 to the second conductive pads 116a. As such, the semiconductor die 120 is electrically connected to the signal source, the power source, and the ground reference.

Reference is made to FIG. 4, which is a cross-sectional view of step S14 of forming the semiconductor package 100 of FIG. 5. In step S14, a second adhesive layer 180 is formed on the semiconductor die 120, and a dummy die 130 is attached to the semiconductor die 120 by the second adhesive layer 180. A conductive layer 140 is then disposed on the dummy die 130. After that, two ends of at least one second conductive wire 160 are bonded to the conductive layer 140 and one of the first conductive pads 114a. Although one of the two ends of the second conductive wire 160 shown in FIG. 4 is bonded to a position near an edge of the conductive layer 140, the end of the second conductive wire 160 can be bonded to any position of the conductive layer 140 as deemed necessary by designers.

Reference is made to FIG. 5, which is a cross-sectional view of step S16 of forming the semiconductor package 100. In step S16, a first molding compound material 200 is formed to encapsulate the semiconductor die 120 and the dummy die 130 as well as the first conductive wires 150 and the second conductive wire 160. A plurality of soldering balls 190 are mounted onto the first conductive pads 114b and the second conductive pads 116b to electrically connect the semiconductor package 100 to external electronic devices. After step S16, the semiconductor package 100 is formed. The aforementioned method is a combination of a fine-pitch ball grid array (FBGA) method and a dual die package (DPP) method.

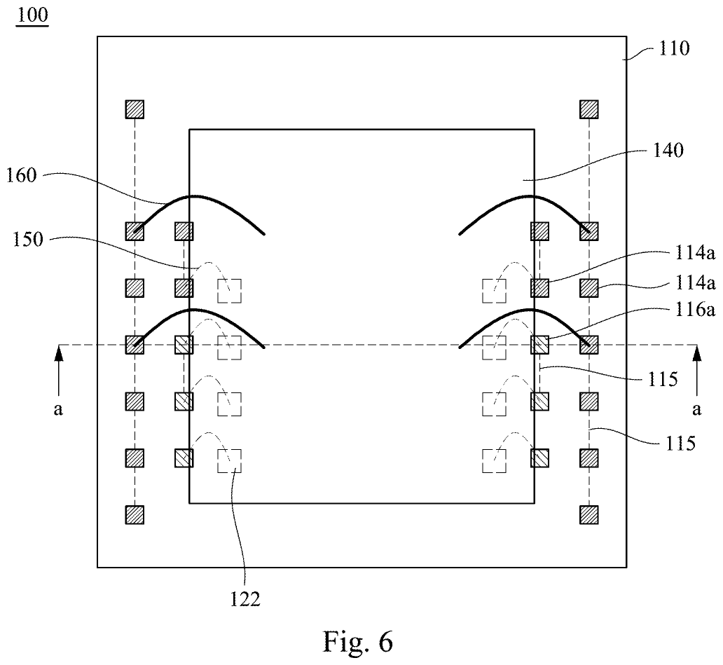

FIG. 6 is a top view of the semiconductor package 100 shown in FIG. 5. It is noted that FIG. 1 and FIGS. 3-5 are cross-sectional views taken along line a-a shown in FIG. 6. Furthermore, the first molding compound material 200 is omitted in FIG. 6. Reference is made to FIGS. 5 and 6. The semiconductor package 100 includes the substrate 110, the semiconductor die 120, the dummy die 130, the conductive layer 140, the first conductive wires 150, and the second conductive wire 160. The semiconductor die 120 is disposed on the substrate 110. The dummy die 130 is disposed on the semiconductor die 120. The conductive layer 140 is disposed on the dummy die 130. The first conductive wires 150 electrically connect the semiconductor die 120 to the signal source, the power source, and the ground reference. The second conductive wire 160 electrically connects the conductive layer 140 to the ground reference.

Since the dummy die 130 is disposed on the semiconductor die 120, and the conductive layer 140 is disposed on the dummy die 130 to be electrically connected to the ground reference by the second conductive wire 160, electromagnetic waves generated by the semiconductor die 120 are blocked from interfering with other surrounding electronic devices. Accordingly, the electromagnetic interference (EMI) between the semiconductor package 100 and other surrounding electronic products is prevented, and thus the electromagnetic sensibility (EMS) of the semiconductor package 100 is further improved.

In some embodiments, the semiconductor die 120 may be a memory integrated circuit (memory IC), and the dummy die 130 may be a silicon die without any function. The first adhesive layer 170 attaches the semiconductor die 120 to the substrate 110, and the second adhesive layer 180 attaches the dummy die 130 to the semiconductor die 120. The first adhesive layer 170 may be made of the same material as the second adhesive layer 180. Furthermore, the conductive layer 140 may be made of a material including aluminum, but the present disclosure is not limited in this regard. In other embodiments, the conductive layer 140 may be made of any suitable metallic material.

Since the dummy die 130 is configured to support the conductive layer 140, a vertical projection area Al of the dummy die 130 on the substrate 110 should entirely cover a vertical projection area A2 of the conductive layer 140 on the substrate 110. Furthermore, the vertical projection area A2 of the conductive layer 140 on the substrate 110 should entirely cover a vertical projection area A3 of the semiconductor die 120 on the substrate 110 to ensure the electromagnetic waves generated by the semiconductor die 120 being entirely blocked.

In some embodiments, the first conductive pads 114 are disposed both on the first surface 111 and the second surface 113 of the dielectric layer 112, and the second conductive wire 160 electrically connects the conductive layer 140 to one of the first conductive pads 114a. The first conductive pads 114 may be made of a material including copper (Cu), but the present disclosure is not limited in this regard. Furthermore, a number of the second conductive wire 160 may be more than one, and each of the second conductive wires 160 electrically connects the conductive layer 140 to the corresponding first conductive pad 114a. The second conductive wire 160 may be made of a material including gold (Au), but the present disclosure is not limited in this regard.

In some embodiments, the traces 115 are disposed on the first surface 111 and the second surface 113 of the dielectric layer 112. The traces 115 interconnect the first conductive pads 114a and further interconnect the first conductive pads 114b. Furthermore, the conductive structures 118 penetrate through the dielectric layer 112 and electrically connect the first conductive pads 114a to the corresponding first conductive pads 114b. Additionally, the soldering balls 190 electrically connect the first conductive pads 114b to a printed circuit board (PCB) to further connect to the ground reference. Accordingly, the conductive layer 140 is electrically connected to the ground reference through various interconnections between the first conductive pads 114, the traces 115, the conductive structures 118, and the soldering balls 190.

In some embodiments, the second conductive pads 116 are disposed both on the first surface 111 and the second surface 113 of the dielectric layer 112, and the first conductive wires 150 electrically connect the semiconductor die 120 to the first conductive pads 114b and the second conductive pads 116b. The second conductive pads 116 may be made of a material including copper (Cu), but the present disclosure is not limited in this regard. The first conductive wires 150 may be made of a material including gold (Au), but the present disclosure is not limited in this regard.

In some embodiments, the traces 115 interconnect the second conductive pads 116a and further interconnect the second conductive pads 116b. In detail, some of the traces 115 interconnect the second conductive pads 116 connected to the signal source, and the other of the traces 115 interconnect the second conductive pads 116 connected to the power source. Furthermore, the second conductive pads 116a are electrically connected to the corresponding second conductive pads 116b by the conductive structures 118. The soldering balls 190 electrically connect the second conductive pads 116b to a printed circuit board (PCB) to further connect to a controller, a monitor, or any electronic devices. Accordingly, the semiconductor die 120 is electrically connected to the signal source and the power source through various interconnections between the second conductive pads 116, the traces 115, the conductive structures 118, and the soldering balls 190. Additionally, the semiconductor die 120 is electrically connected to the ground reference through various interconnections between the first conductive pads 114, the traces 115, the conductive structures 118, and the soldering balls 190.

The soldering masks 119 protect the traces 115 on the first surface 111 and the second surface 113 of the dielectric layer 112 and further prevent the traces 115 from shorting. The soldering masks 119 may be made of a material including dielectrics, such as resin, but the present disclosure is not limited in this regard.

The first molding compound material 200 encapsulates the semiconductor die 120 and the dummy die 130. In some embodiments, the first molding compound material 200 further encapsulates the first conductive wires 150 and the second conductive wire 160. The first molding compound material 200 may be made of a material including resin, but the present disclosure is not limited in this regard.

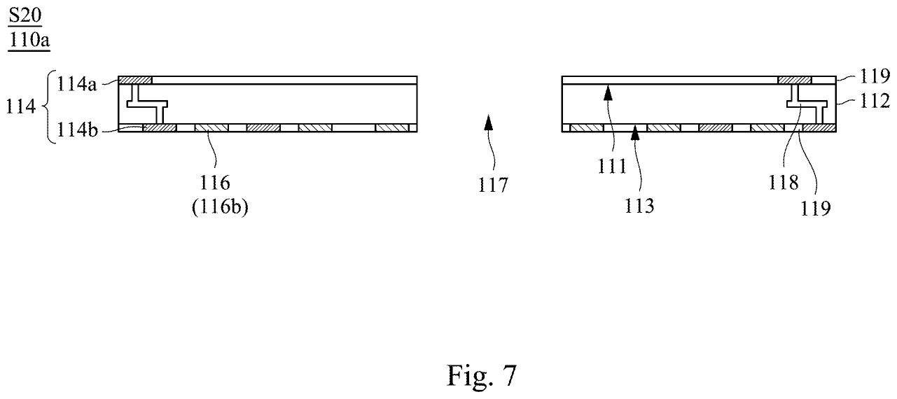

In the following description, a manufacturing method of a semiconductor package 100a will be described. Since some steps of FIGS. 7-11 are similar to those corresponding steps of FIGS. 1-5, descriptions for those similar steps will not be repeated hereinafter.

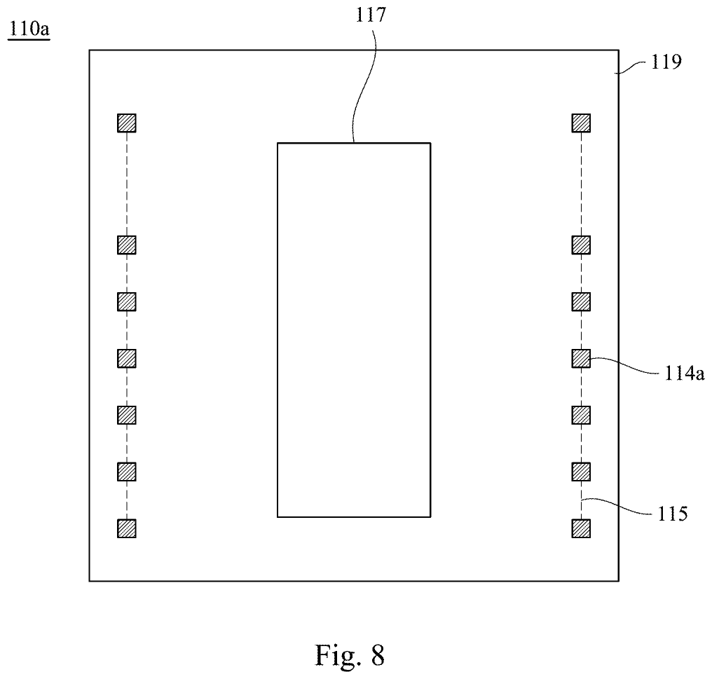

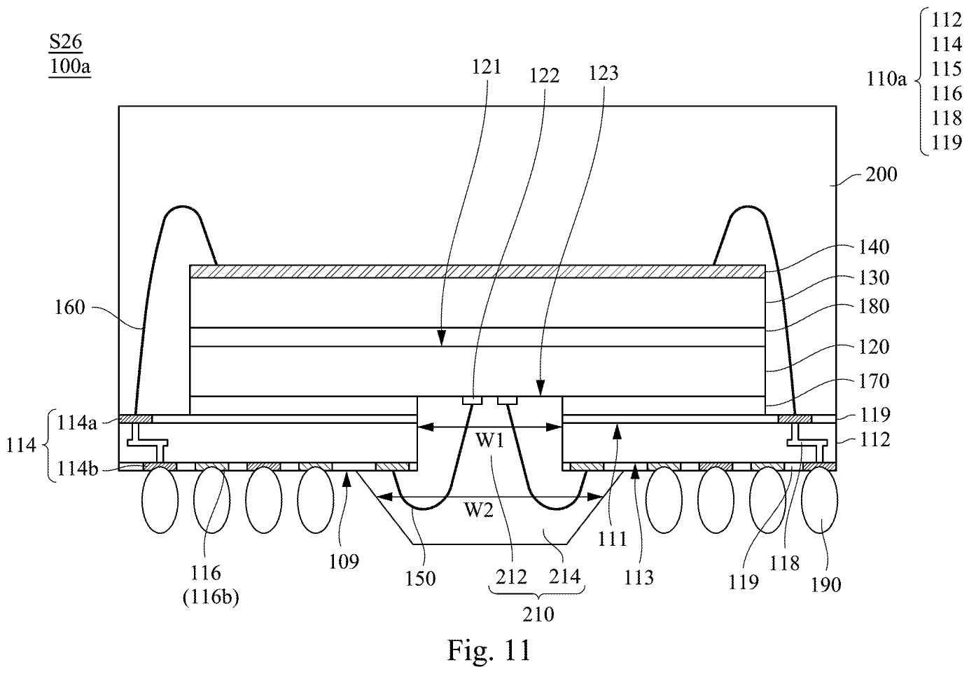

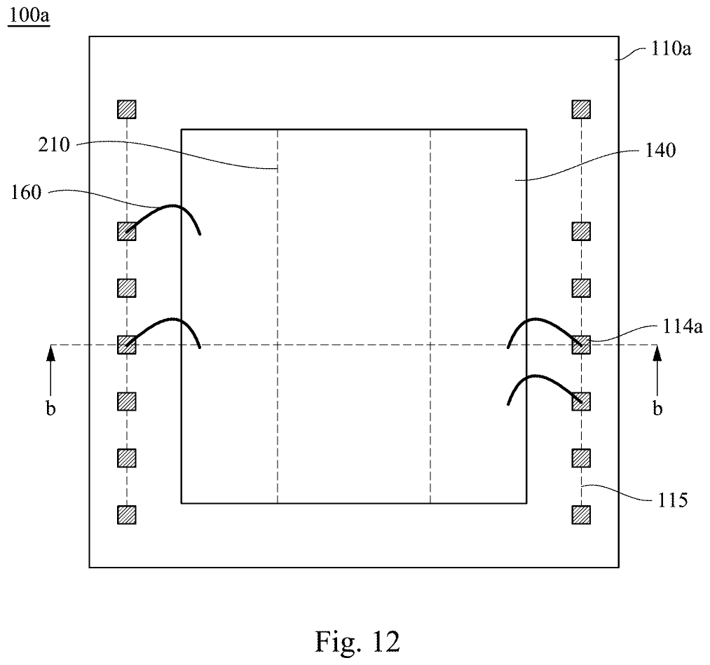

Reference is made to FIGS. 7 and 8, which are a cross-sectional view and a top view of step S20 of forming the semiconductor package 100a of FIG. 11. In step S20, a dielectric layer 112 having a first surface 111 and a second surface 113 is provided. A through hole 117 is formed penetrating through the dielectric layer 112. A plurality of first conductive pads 114, a plurality of traces 115, a plurality of second conductive pads 116, a plurality of conductive structures 118, and two soldering masks 119 are formed such that a substrate 110a can be obtained.

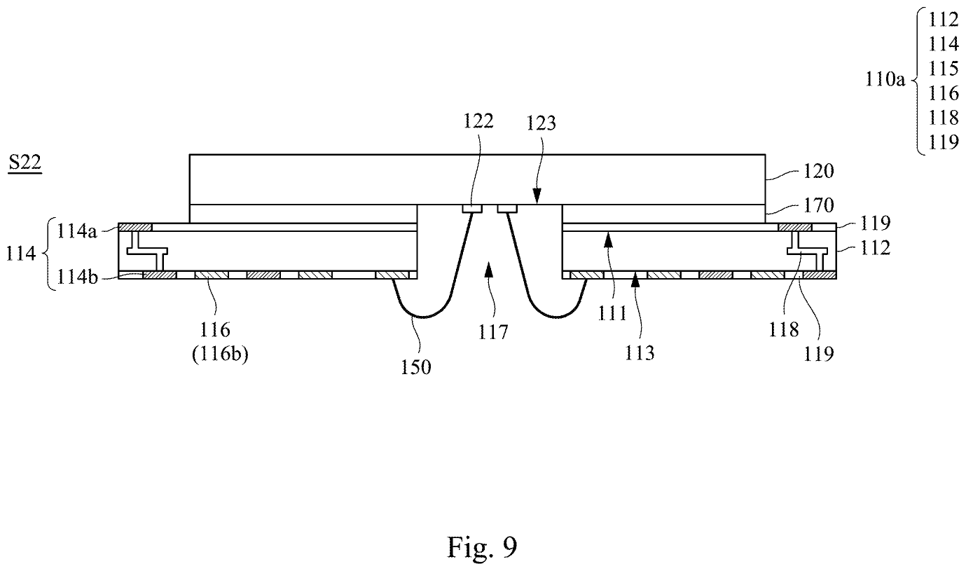

Reference is made to FIG. 9, which is a cross-sectional view of step S22 of forming the semiconductor package 100a of FIG. 11. In step S22, a first adhesive layer 170 is formed on one of the soldering masks 119 disposed on the first surface 111 of the dielectric layer 112. A semiconductor die 120 is then attached to the substrate 110a by the first adhesive layer 170, and a portion of a bottom surface 123 of the semiconductor die 120 is exposed from the through hole 117. A plurality of third conductive pads 122 are disposed on a bottom surface 123 of the semiconductor die 120. After that, a plurality of first conductive wires 150 are respectively connected from the third conductive pads 122 to the conductive pads on the second surface 113 of the dielectric layer 112. In detail, some of the first conductive wires 150 are connected from the third conductive pads 122 to the first conductive pads 114b, and the other of the first conductive wires 150 are connected from the third conductive pads 122 to the second conductive pads 116b. As such, the semiconductor die 120 is electrically connected to the signal source, the power source, and the ground reference.

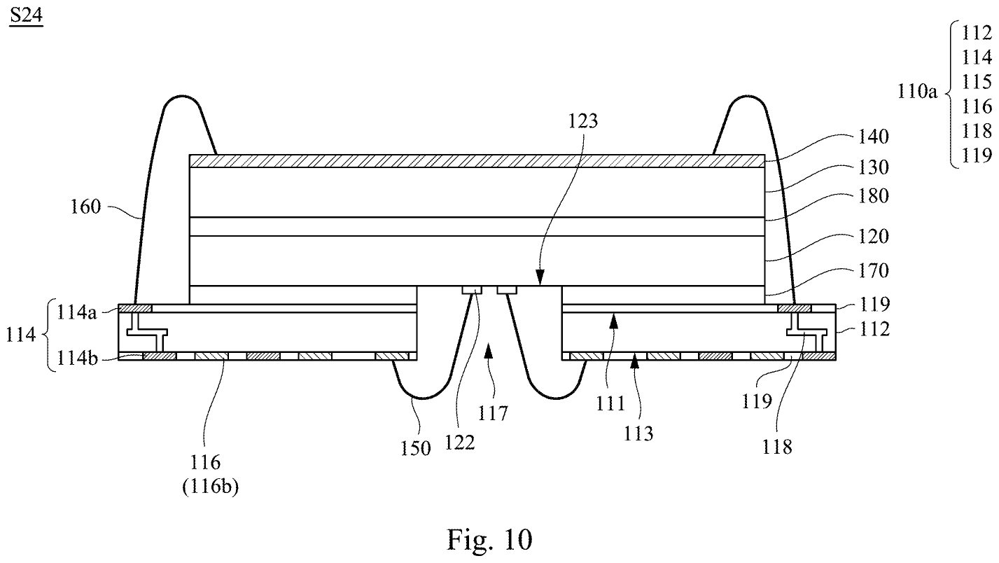

Reference is made to FIG. 10, which is a cross-sectional view of step S24 of forming the semiconductor package 100a. In step S24, a second adhesive layer 180 is formed on the semiconductor die 120, and a dummy die 130 is attached to the semiconductor die 120 by the second adhesive layer 180. A conductive layer 140 is then disposed on the dummy die 130. After that, two ends of at least one second conductive wire 160 are respectively bonded to the conductive layer 140 and one of the first conductive pads 114a. Although one of the two ends of the second conductive wire 160 shown in FIG. 10 is bonded to a position near an edge of the conductive layer 140, the end of the second conductive wire 160 can be bonded to any position of the conductive layer 140 as deemed necessary by designers.

Reference is made to FIG. 11, which is a cross-sectional view of step S26 of forming the semiconductor package 100a. In step S26, a first molding compound material 200 is formed to encapsulate the semiconductor die 120, the dummy die 130, and the second conductive wire 160. A second molding compound material 210 is formed to fill the through hole 117 and cover a portion of a bottom surface 109 of the substrate 110a in order to encapsulate the first conductive wires 150. The second molding compound material 210 further covers portions of the second conductive pads 116b bonded by the first conductive wires 150. A plurality of soldering balls 190 are mounted onto the first conductive pads 114b and the second conductive pads 116b which are not bonded by the first conductive wires 150, and thus the semiconductor package 100a can electrically connect to external electronic devices. After step S26, the semiconductor package 100a is formed. The aforementioned method is a combination of a window ball grid array (WBGA) method and a dual die package (DPP) method.

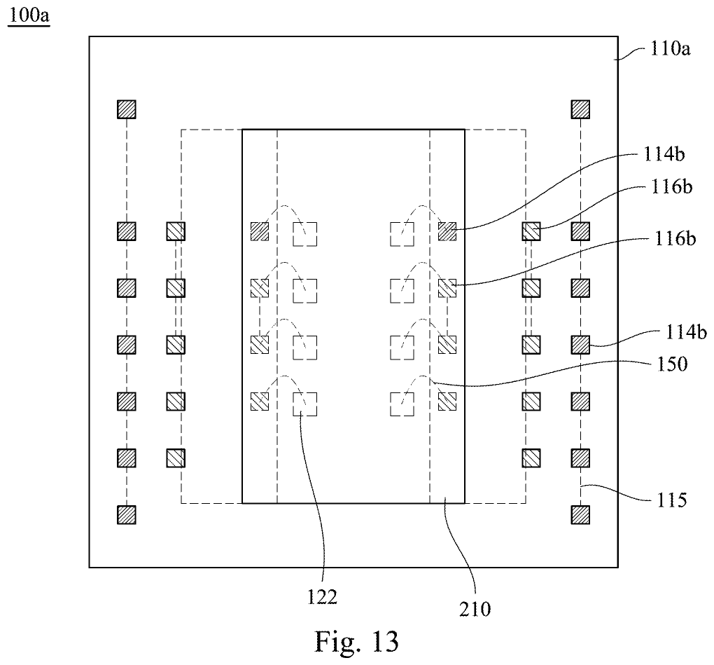

FIG. 12 is a top view of the semiconductor package 100a shown in FIG. 11. FIG. 13 is a bottom view of the semiconductor package 100a shown in FIG. 11. It is noted that FIGS. 7 and 9-11 are cross-sectional views taken along line b-b shown in FIG. 12. Furthermore, the first molding compound material 200 is omitted in FIG. 12, and the soldering balls 190 are omitted in FIG. 13. Reference is made to FIGS. 11-13. In comparison with the aforementioned semiconductor package 100, the semiconductor die 120 is electrically connected to signal source, the power source, and the ground reference through the third conductive pads 122 on the bottom surface 123 of the semiconductor die 120. Additionally, the semiconductor package 100a further includes a second molding compound material 210 encapsulating the first conductive wires 150.

In some embodiments, the second conductive pads 116 within the semiconductor package 100a may only be disposed on the second surface 113 of the dielectric layer 112. In other words, the semiconductor package 100a may only include the second conductive pads 116b, but the present disclosure is not limited in this regard. In other embodiments, the semiconductor package 100a may further include the second conductive pads 116a selectively disposed on the first surface 111 of the dielectric layer 112 as deemed necessary by designers.

In some embodiments, the first molding compound material 200 within the semiconductor package 100a encapsulates the semiconductor die 120, the dummy die 130, and the second conductive wire 160, while the second molding compound material 210 encapsulates the first conductive wires 150. The second molding compound material 210 has a first portion 212 and a second portion 214. The first portion 212 penetrates through the substrate 110a (including the dielectric layer 112 and the soldering masks 119) and is in contact with the bottom surface 123 of the semiconductor die 120, and the second portion 214 is disposed on a portion of the bottom surface 109 of the substrate 110a.

In some embodiments, the first adhesive layer 170 within the semiconductor package 100a surrounds a portion of the first portion 212 of the second molding compound material 210. Furthermore, the first adhesive layer 170 is in contact with the portion of the first portion 212 of the second molding compound material 210.

In some embodiments, a width W1 of the first portion 212 of the second molding compound material 210 is smaller than a width W2 of the second portion 214 of the second molding compound material 210. A cross-sectional shape of the second portion 214 of the second molding compound material 210 may be a triangle, a rectangle, a trapezoid, or other suitable geometric shapes, but the present disclosure is not limited in this regard. Furthermore, the second portion 214 of the second molding compound material 210 covers portions of the second conductive pads 116b bonded by the second conductive wire 160. Additionally, the soldering balls 190 within the semiconductor package 100a may only be connected to the second conductive pads 116b which are not bonded by the first conductive wire 150.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

What is claimed is:

1. A semiconductor package, comprising:
a substrate;
a semiconductor die disposed on the substrate;
a dummy die disposed on the semiconductor die;
a conductive layer disposed on the dummy die;
at least one first conductive wire electrically connecting the semiconductor die to a signal source; and
at least one second conductive wire electrically connecting the conductive layer to a ground reference.

2. The semiconductor package of claim 1, wherein a vertical projection area of the conductive layer on the substrate covers a vertical projection area of the semiconductor die on the substrate.

3. The semiconductor package of claim 1, further comprising:
a first molding compound material encapsulating the semiconductor die and the dummy die.

4. The semiconductor package of claim 3, wherein the first molding compound material further encapsulates the first conductive wire and the second conductive wire.

5. The semiconductor package of claim 1, further comprising:
a first adhesive layer attaching the semiconductor die to the substrate; and
a second adhesive layer attaching the dummy die to the semiconductor die.

6. The semiconductor package of claim 1, wherein the substrate further comprises:
a dielectric layer having a first surface and a second surface; and
a plurality of conductive pads disposed on the first surface and the second surface of the dielectric layer.

7. The semiconductor package of claim 6, wherein the substrate further comprises:
a plurality of traces interconnecting the conductive pads on the first surface of the dielectric layer or the conductive pads on the second surface of the dielectric layer.

8. The semiconductor package of claim 6, wherein the substrate further comprises:
a plurality of conductive structures extending through the dielectric layer, wherein the conductive structures electrically connect the conductive pads on the first surface of the dielectric layer to the corresponding conductive pads on the second surface of the dielectric layer.

9. The semiconductor package of claim 6, further comprising:
a plurality of soldering balls electrically connected to the conductive pads on the second surface.

10. The semiconductor package of claim 6, wherein the substrate further comprises:
two soldering masks disposed on the first surface and the second surface of the dielectric layer, respectively.

11. The semiconductor package of claim 1, further comprising:
a second molding compound material having a first portion and a second portion, wherein the first portion penetrates through the substrate, and second portion is disposed on a bottom surface of the substrate.

12. The semiconductor package of claim 11, wherein the first portion of the second molding compound material is in contact with a bottom surface of the semiconductor die.

13. The semiconductor package of claim 11, wherein the second molding compound material encapsulates the first conductive wire.

14. The semiconductor package of claim 11, wherein a width of the first portion of the second molding compound material is smaller than a width of the second portion of the second molding compound material.

15. The semiconductor package of claim 11, further comprising:
a first adhesive layer attaching the semiconductor die to the substrate; and
a second adhesive layer attaching the dummy die to the semiconductor die.

16. The semiconductor package of claim 15, wherein the first adhesive layer surrounds a portion of the first portion of the second molding compound material.

17. The semiconductor package of claim 16, wherein the first adhesive layer is in contact with the portion of the first portion of the second molding compound material.

18. The semiconductor package of claim 11, further comprising:
a dielectric layer having a first surface and a second surface; and
a plurality of conductive pads disposed on the first surface and the second surface of the dielectric layer.

19. The semiconductor package of claim 18, further comprising:
a plurality of soldering balls electrically connected to portions of the conductive pads on the second surface of the dielectric layer.

20. The semiconductor package of claim 18, wherein the second portion of the second molding compound material covers portions of the conductive pads on the second surface of the dielectric layer.
